(19) United States
(12) Patent Application Publication
(10) Pub. No.: US 2008/0303069 A1
(43) Pub. Date: Dec. 11, 2008

(54) TWO STEP PHOTORESIST STRIPPING METHOD SEQUENTIALLY USING ION ACTIVATED AND NON-ION ACTIVATED NITROGEN CONTAINING PLASMAS

(75) Inventors: Nicholas C.M. Fuller, Ossining, NY (US); Solomon Assefa, Elmsford, NY (US); Ying Zhang, Yorktown Heights, NY (US)

Correspondence Address: SCULLY, SCOTT, MURPHY & PRESSER, P.C., 400 GARDEN CITY PLAZA, SUITE 300, GARDEN CITY, NY, 11530, US

(73) Assignee: INTERNATIONAL BUSINESS MACHINES CORPORATION, Armonk, NY (US)

(21) Appl. No.: 11/760,885

(22) Filed: Jun. 11, 2007

(51) Int. Cl. H01L 21/467; H01L 29/78

(52) U.S. Cl. 257/288; 438/714; 257/E29.255; 257/E21.486

(57) ABSTRACT

A two-step nitrogen plasma method is used for stripping a photoresist layer from over a substrate. A first step within the two-step nitrogen plasma method uses a nitrogen plasma with ion activation to form from the photoresist layer over the substrate a treated photoresist layer over the substrate. A second step within the two-step nitrogen plasma method uses a second nitrogen plasma without ion activation to remove the treated photoresist layer from over the substrate. The method is particularly useful for stripping a patterned photoresist layer that is used for forming a gate electrode from a gate electrode material layer.

### BACKGROUND

1. Field of the Invention

The invention relates generally to photoresist layers used for fabricating microelectronic structures. More particularly, the invention relates to methods for stripping photoresist layers used for fabricating microelectronic structures.

2. Description of the Related At

Microelectronic structures, and in particular semiconductor structures, are generally formed by patterning blanket layers that are formed over microelectronic substrates. The patterned layers that are formed from the blanket layers are generally formed using a plasma etch method that uses a patterned photoresist layer as an etch mask layer. Within the context of semiconductor structures, and in particular within the context of field effect transistors within semiconductor structures, gate electrodes are often patterned from gate electrode material layers while using patterned photoresist layers as etch mask layers.

As semiconductor technology has advanced, the use of alternative materials (i.e., in comparison with conventional monocrystalline silicon materials and polycrystalline silicon materials) for semiconductor substrates and gate electrodes has evolved. For semiconductor substrates, such alternative materials may include, but are not necessarily limited to, germanium materials and silicon-germanium alloy materials. For gate electrodes, such alternative materials may include, but are not necessarily limited to, germanium materials, silicon-germanium alloy materials, metal materials, metal alloy materials, metal nitride materials and metal silicide materials. Often, these alternative gate electrode materials are selected specifically within the context of an nFET device and a pFET device in order to provide a specific and separate work function within an nFET gate electrode in comparison with a pFET gate electrode. In turn the differing work functions for the nFET gate electrode in comparison with the pFET gate electrode provide for individually enhanced performance of the nFET device in comparison with the pFET device.

While the different materials of composition of an nFET gate electrode in comparison with a pFET gate electrode within a semiconductor structure such as but not limited to a CMOS structure are certainly desirable for purposes of individually optimizing an nFET performance in comparison with a pFET performance, such differences in materials of composition are not entirely without problems. In particular, the etching of the different nFET gate electrode and pFET gate electrode from different gate electrode materials compositions often provides patterned photoresist etch mask layers that may be difficult to remove from the nFET gate electrode and the pFET gate electrode due to the presence therein of atypical gate electrode material layer residues.

As semiconductor structure and device dimensions continue to decrease and semiconductor structure and device performance requirements continue to increase, so also will continue the likelihood that nFET gate electrodes and pFET gate electrodes within semiconductor structures will be fabricated from novel gate electrode materials that may be selected predicated upon differential work functions that may be selected to optimize nFET devices and pFET devices within which are located the nFET gate electrodes and pFET gate electrodes. To that end, also desirable are novel methods and materials for stripping photoresist etch masks from those nFET gate electrodes and pFET gate electrodes, where the photoresist etch masks may in part include etch residues from novel gate electrode materials from which are comprised the nFET gate electrodes and the pFET gate electrodes.

### SUMMARY OF THE INVENTION

The invention provides a method for stripping a photoresist layer, generally but not necessarily exclusively from a patterned structure within a microelectronic structure, such as but not limited to a semiconductor structure. The microelectronic structure from which may be stripped the photoresist layer may include, but is not necessarily limited to, a fully patterned microelectronic layer, a partially patterned microelectronic layer or alternatively a trench within a microelectronic substrate. The photoresist layer is generally but not exclusively a patterned photoresist layer that includes a residue therein that may not readily be removable using an oxygen plasma stripping method and/or wet chemical stripping method.

The photoresist stripping method in accordance with the invention comprises a two-step nitrogen plasma based photoresist stripping method. A first step within the inventive two-step nitrogen plasma based photoresist stripping method uses an ion activated nitrogen containing plasma (i.e., a nitrogen containing plasma that is electrically biased with respect to a substrate) to treat a surface layer of the photoresist layer located over the substrate to provide a surface layer treated photoresist layer located over the substrate. A second step within the two-step nitrogen plasma based photoresist stripping method uses a non-ion activated nitrogen containing plasma (i.e., a nitrogen containing plasma that is at least substantially not electrically biased with respect to the substrate) to remove the surface layer treated photoresist layer located over the substrate. The method in accordance with the invention also provides that a first temperature (i.e., substrate and overlying layer temperature) used within first step is less than a second temperature (i.e., substrate and overlying layer temperature) used within the second step.

A particular semiconductor structure that may be fabricated in accordance with a method in accordance with the invention includes a patterned germanium layer having a photoresist layer etch residue of less than about 1 area percent.

A particular method for stripping a photoresist layer in accordance with the invention includes treating a photoresist layer located over a substrate with a first nitrogen containing plasma that uses an ion activation to provide a treated photoresist layer located over the substrate. This particular method also includes removing the treated photoresist layer from over the substrate with a second nitrogen containing plasma that does not use the ion activation.

A particular method for forming a patterned structure in accordance with the invention includes patterning a substrate to form a patterned substrate while using a photoresist layer located over the substrate as an etch mask layer. This particular method also includes treating the photoresist layer located over the patterned substrate with a first nitrogen containing plasma that uses an ion activation to provide a treated photoresist layer located over the patterned substrate. This particular method also includes removing the treated photoresist layer from over the patterned substrate with a second nitrogen containing plasma that does not use the ion activation.

### BRIEF DESCRIPTION OF THE DRAWINGS

The objects, features and advantages of the invention are understood within the context of the description of the preferred embodiment, as set forth below. The description of the preferred embodiment is understood within the context of the accompanying drawings, which form a material part of this disclosure, wherein:

FIG. 1 to FIG. 5 show a series of schematic cross-sectional diagrams illustrating the results of progressive stages in fabricating a semiconductor structure using a method in accordance with a preferred embodiment of the invention.

### DESCRIPTION OF THE PREFERRED EMBODIMENT

The invention, which includes a method for stripping a photoresist layer located over a substrate used in a microelectronic structure, is understood within the context of the description as set forth below. The description as set forth below is understood within the context of the drawings described above. Since the drawings are intended for illustrative purposes, the drawings are not necessarily drawn to scale.

Although the preferred embodiment illustrates the invention within the context of fabricating a gate electrode within a field effect transistor within a semiconductor structure, where in particular a patterned photoresist layer is removed from the gate electrode within the field effect transistor while using a two-step nitrogen containing plasma etch method in accordance with the invention, the invention is not necessarily intended to be so limited. Rather, the invention may be used for removing a photoresist layer (i.e., typically a patterned photoresist layer) from a structure (i.e., typically a patterned structure) within a microelectronic structure or a semiconductor structure. Within the context of the invention in general, the structure may include at least either a patterned layer, or a trench (i.e., an aperture) located within a substrate. The patterned layer, or the substrate within which is located the trench, may comprise a material including but not limited to a conductor material, a semiconductor material or a dielectric layer.

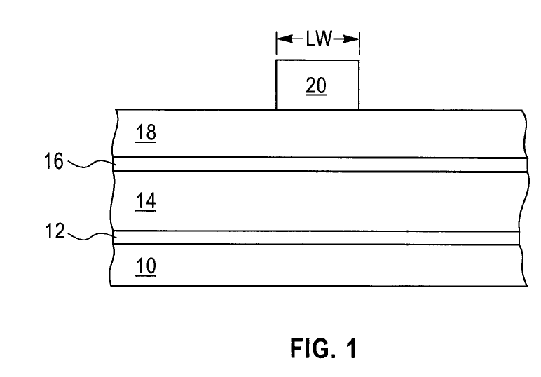

FIG. 1 to FIG. 5 show a series of schematic cross-sectional diagrams illustrating the results of progressive stages in fabricating a semiconductor structure in accordance with a preferred embodiment of the invention.

FIG. 1 shows a semiconductor substrate 10. A buried dielectric layer 12 is located upon the semiconductor substrate 10. A surface semiconductor layer 14 is located upon the buried dielectric layer 12. In an aggregate, the semiconductor substrate 10, the buried dielectric layer 12 and the surface semiconductor layer 14 comprise a semiconductor-on-insulator substrate.

The semiconductor substrate 10 may comprise any of several semiconductor materials. Non-limiting examples include silicon, germanium, silicon-germanium alloy, silicon-carbon alloy, silicon-germanium-carbon alloy and compound (i.e., III-V and II-VI) semiconductor materials. Non-limiting examples of compound semiconductor materials include gallium arsenide, indium arsenide and indium phosphide semiconductor materials. Typically, the semiconductor substrate 10 has a generally conventional thickness from about 1 to about 3 mils.

The buried dielectric layer 12 may comprise any of several dielectric materials. Non-limiting examples include oxides, nitrides and oxynitrides, particularly of silicon, but oxides, nitrides and oxynitrides of other elements are not excluded. The buried dielectric layer 12 may comprise a crystalline or a non-crystalline dielectric material, with crystalline dielectric materials being highly preferred. The buried dielectric layer 12 may be formed using any of several methods. Non-limiting examples include ion implantation methods, thermal or plasma oxidation or nitridation methods, chemical vapor deposition methods and physical vapor deposition methods. Typically, the buried dielectric layer 12 comprises an oxide of the semiconductor material from which is comprised the semiconductor substrate 10. Typically, the buried dielectric layer 12 has a conventional thickness from about 50 to about 200 angstroms.

The surface semiconductor layer 14 may comprise any of the several semiconductor materials from which the semiconductor substrate 10 may be comprised. The surface semiconductor layer 14 and the semiconductor substrate 10 may comprise either identical or different semiconductor materials with respect to chemical composition, dopant polarity, dopant concentration and crystallographic orientation. Typically, the surface semiconductor layer 14 has a conventional thickness from about 500 to about 1000 angstroms.

The semiconductor-on-insulator substrate that is illustrated in FIG. 1 may be fabricated using any of several methods. Non-limiting examples include layer lamination methods, layer transfer methods and separation by implantation of oxygen (SIMOX) methods.

Although the embodiment illustrates the invention within the context of a semiconductor on-insulator substrate comprising the semiconductor substrate 10, the buried dielectric layer 12 and the surface semiconductor layer 14, neither the embodiment, nor the invention, is so limited. Rather, the present invention may alternatively be practiced using a bulk semiconductor substrate (that would otherwise result from absence of the buried dielectric layer 12 under circumstances where the semiconductor substrate 10 and the surface semiconductor layer 14 have identical chemical composition and crystallographic orientation). The embodiment also contemplates use of a hybrid orientation (HOT) substrate that has multiple crystallographic orientations within a single semiconductor substrate.

FIG. 1 also shows (in cross-section): (1) a gate dielectric 16 located upon the surface semiconductor layer 14; and (2) a gate electrode material layer 18 located upon the gate dielectric 16.

The gate dielectric 16 may comprise conventional dielectric materials such as oxides, nitrides and oxynitrides of silicon that have a dielectric constant from about 4 to about 20, measured in vacuum. Alternatively, the gate dielectric 16 may comprise generally higher dielectric constant dielectric materials having a dielectric constant from about 20 to at least about 100. Such higher dielectric constant dielectric materials may include, but are not limited to hafnium oxides, hafnium silicates, titanium oxides, barium-strontium-titantates (BSTs) and lead-zirconate-titanates (PZTs). The gate dielectric 16 may be formed using any of several methods that are appropriate to its material(s) of composition. Included, but not limiting are thermal or plasma oxidation or nitridation methods, chemical vapor deposition methods and physical vapor deposition methods. Typically, the gate dielectric 16 comprises a thermal silicon oxide dielectric material that has a conventional thickness from about 10 to about 70 angstroms.

The gate electrode material layer 18 may comprise materials including, but not limited to certain metals, metal alloys, metal nitrides and metal silicides, as well as laminates thereof and composites thereof. The gate electrode material layer 18 may also comprise doped polysilicon (although not particularly preferred within the embodiment) polygermanium and polysilicon-germanium alloy materials (i.e., having a dopant concentration from about 1e18 to about 1e22 dopant atoms per cubic centimeter) and polycide materials (doped polysilicon or polygermanium/metal silicide stack materials). Similarly, the foregoing materials may also be formed using any of several methods. Non-limiting examples include salicide methods, chemical vapor deposition methods and physical vapor deposition methods, such as, but not limited to evaporative methods and sputtering methods. Typically, the gate electrode material layer 18 comprises other than a doped polysilicon material (i.e. within the context of the above disclosed alternatives) that has a generally conventional thickness from about 600 to about 2000 angstroms. FIG. 1 finally shows photoresist layer 20 located upon the gate electrode material layer 18.

The photoresist layer 20 may comprise any of several photoresist materials. Non-limiting examples include positive photoresist materials, negative photoresist materials and hybrid (i.e., positive and negative) photoresist materials. Positive photoresist materials and negative photoresist materials are generally more common, but positive photoresist materials and negative photoresist materials by no means limit the invention. Typically, the photoresist layer 20 comprises a positive photoresist material or a negative photoresist material that has a conventional thickness in a range from about 750 to about 3000 angstroms, as well as a conventional linewidth LW over the gate electrode material layer 18 from about 50 to about 200 nanometers.

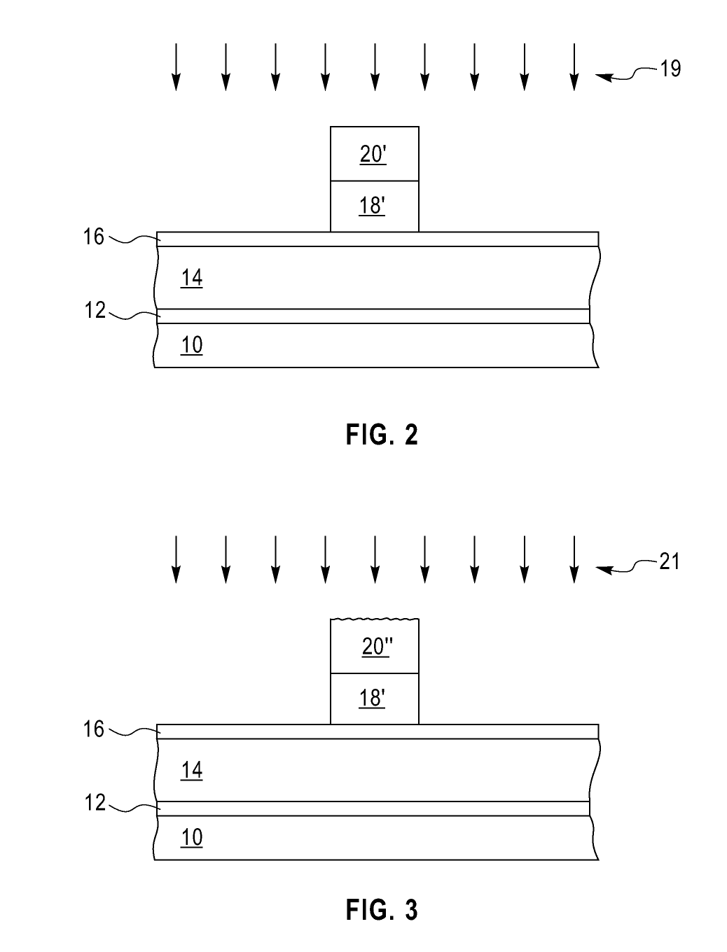

FIG. 2 shows the results of etching the gate electrode material layer 18 to form a gate electrode 18′ while using the photoresist layer 20 as an etch mask layer, in conjunction with the etching plasma 19. As a result of the foregoing etching, the photoresist layer 20 is transformed into a residue laden photoresist layer 20′. The etching plasma 19 comprises an etchant gas composition appropriate to the material of composition of the gate electrode material layer 18. Fluorine containing etchant gas compositions, chlorine containing etchant gas compositions and bromine containing etchant gas compositions are common, but by no means limit the invention. Other etchant gas compositions are not excluded. When etching the gate electrode material layer 18 to form the gate electrode 18′ while using the photoresist layer 20 as an etch mask layer, the resulting residue laden photoresist layer 20′ will typically become residue laden from both the etchant gas composition and any other unique materials from which is comprised the semiconductor structure whose schematic cross-sectional diagram is illustrated in FIG. 2, and in particular unique metal materials from which may be comprised the gate electrode material layer 18. Particularly common are germanium residues and metal residues, such as but not limited to transitional metal residues.

It is thus towards the goal of removing the residue laden photoresist layer 20′ from the gate electrode 18′, in a fashion that leaves no residue of the residue laden photoresist layer 20′ upon the gate electrode 18′, that the embodiment and the invention are directed. Similarly, in order to achieve the foregoing result, the embodiment and the invention use a two-step nitrogen containing plasma etch method. Within the two-step nitrogen containing plasma etch method, a first step uses an ion activated nitrogen containing plasma (i.e., a nitrogen containing plasma that has an electrical bias with respect to the substrate 10) at a first temperature that is intended to at least treat and therefore possibly modify, or alternatively remove, a surface layer of the residue laden photoresist layer 20′ to provide a treated photoresist layer. Within the two step nitrogen containing plasma etch method, the second step uses a non-ion activated nitrogen containing plasma (e.g., a nitrogen containing plasma that has no substantial electrical bias (i.e., less than about 5 eV with respect to the substrate 10) at a second temperature greater than the first temperature, where the second temperature is intended to assist in removing the treated photoresist layer absent damage to, or a residue upon, the gate electrode 18′. For most standard photoresist compositions that are generally disclosed above, the first temperature is no greater than about 130 degrees centigrade, and typically from about 10 to about 130 degrees centigrade, while the second temperature is no less than about 200 degrees centigrade, and typically from about 200 to about 350 degrees centigrade.

FIG. 3 shows the results of treating the residue laden photoresist layer 20′ within a first nitrogen containing plasma 21, in accordance with the above description, to form a treated photoresist layer 20″. The first nitrogen containing plasma 21 (as well as a subsequent nitrogen containing plasma described below) may comprise nitrogen (N₂), as well as other nitrogen containing species that are generally non-oxidizing. Such other nitrogen containing species may include, but are not limited to ammonia (NH₃) and hydrazine (N₂H₄). The first nitrogen containing plasma 21 is also optimized within the context of particular plasma discharge parameters in a fashion that minimizes a hydrogen (i.e., H) radical concentration within the first nitrogen containing plasma 21. The first nitrogen containing plasma 21 typically uses: (1) a reactor chamber pressure from about 10 to about 200 mtorr; (2) a substrate 10 and overlying layers temperature from about 10 to about 130 degrees centigrade; (3) a source (i.e., including but not limited to inductively coupled plasma (ICP), electron cyclotron resonance (ECR), microwave or Helicon source) radio frequency power from about 200 to about 2500 watts; (4) a substrate 10 bias (at any particular frequency although 13.56 MHz is a particularly common frequency) from about 20 to about 500 watts and more preferably from about 50 to about 200 watts; (5) a nitrogen flow rate from about 50 to about 500 standard cubic centimeters per minute (sccm); and (6) an inert carrier gas, such as argon, neon, helium, xenon or krypton, flow rate of up to about 500 standard cubic centimeters per minute (sccm).

The first nitrogen containing plasma 21 treatment of the residue laden photoresist layer 20′ to form the treated photoresist layer 20″ may be monitored to an endpoint by monitoring a concentration of a carbon and nitrogen (i.e., C and N) containing species within an effluent gas from the first nitrogen containing plasma 21 treatment. Various analytical techniques may be used, including but not limited to plasma analysis methods and mass spectroscopy analysis methods.

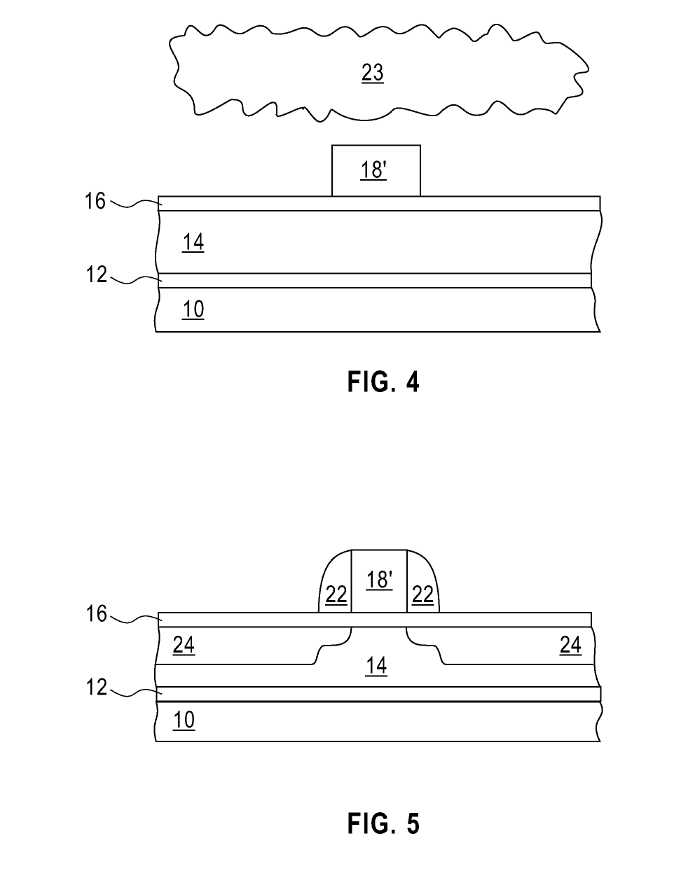

FIG. 4 shows the results of removing the treated photoresist layer 20″ that is illustrated in FIG. 3 from the gate electrode 18′. In accordance with disclosure above, the treated photoresist layer 20″ is removed from the gate electrode 18′ while using a second nitrogen containing plasma 23 treatment, some particulars of which are described in certain further detail above. More particularly, the second nitrogen containing plasma 23 treatment uses: (1) a reactor chamber pressure from about 0.5 to about 2 torr; (2) a substrate 10 and overlying layers temperature from about 200 to about 350 degrees centigrade; (3) a source (i.e., including but not limited to inductively coupled plasma (ICP), electron cyclotron resonance (ECR), microwave or Helicon source) radio frequency power from about 500 to about 5000 watts; (4) a substrate 10 bias preferably of zero, but in any event less than about 5 eV; (5) a nitrogen flow rate from about 100 to about 10000 standard cubic centimeters per minute (scem); and (6) an inert carrier gas, such as but not limited to helium, neon, argon, xenon or krypton, flow rate of up to about 100000 standard cubic centimeters per minute (sccm).

As is illustrated in FIG. 4, the embodiment intends that the treated photoresist layer 20″ that is illustrated in FIG. 3 is stripped completely from the gate electrode 18′ without leaving a residue, and in particular a residue that might otherwise result from stripping the residue laden photoresist layer 20′ that is illustrated in FIG. 2 while using an oxidizing plasma, such as an oxygen containing oxidizing plasma.

Although not particularly illustrated within the schematic cross-sectional diagrams of FIG. 3 and FIG. 4, the embodiment contemplates various combinations or types of apparatus within which may be provided the first nitrogen containing plasma 21 treatment and the second nitrogen containing plasma 23 treatment. In one particular instance, a downstream plasma asher apparatus that is appropriately modified to provide a substrate 10 bias may be used to provide both the first nitrogen containing plasma 21 treatment and the second nitrogen containing plasma 23 treatment. Alternatively, and without limitation, an inductively coupled plasma apparatus may be used to provide the first nitrogen containing plasma 21 treatment and a downstream asher apparatus may be used to provide the second nitrogen containing plasma 23 treatment.

FIG. 5 shows the results of further processing of the semiconductor structure whose schematic cross-sectional diagram is illustrated in FIG. 4.

FIG. 5 shows a spacer 22 adjoining opposite sidewalls (in cross-section, but completely surrounding in plan-view) of the gate electrode 18′. The spacer 22 may comprise materials including, but not limited to conductor materials and dielectric materials. Conductor spacer materials are less common, but are nonetheless known. Dielectric spacer materials, such as but not limited to oxides, nitrides and oxynitrides of silicon, are more common. The spacer materials may generally be formed using layer deposition methods that are conventional in the art. Non-limiting examples include methods analogous, equivalent or identical to the methods that are used for forming the buried dielectric layer 12. The spacer 22 is also formed with the distinctive inward pointing spacer shape by using a blanket layer deposition and anisotropic etchback method. Typically, the spacer 22 comprises a silicon oxide dielectric material.

Finally, FIG. 5 shows a plurality of source/drain regions 24 that comprise a generally conventional n conductivity type dopant or p conductivity type dopant of chemical composition that is otherwise generally conventional in the semiconductor fabrication art. As is understood by a person skilled in the art, the plurality of source/drain regions 24 is formed using a two-step ion implantation method. A first ion implantation process step within the method uses the gate electrode 18′, absent the spacer 22, as a mask to form a pair of extension regions each of which extends beneath the spacer 22. A second ion implantation process step uses the gate electrode 18′ and the spacer 22 as a mask to form the larger contact region portions of the plurality of source/drain regions 24, while simultaneously incorporating the extension regions. n conductivity type dopant levels or p conductivity dopant levels are from about 1e19 to about 1e21 dopant atoms per cubic centimeter within each of the plurality of source/drain regions 24. Extension regions within the plurality of source/drain regions 24 may under certain circumstances be more lightly doped than contact regions with the plurality of source/drain regions, although such differential doping concentrations are not a requirement of the invention.

FIG. 5 shows a schematic cross-sectional diagram of a semiconductor structure in accordance with a particular embodiment of the invention. The semiconductor structure includes a gate electrode 18′ which is patterned from a gate electrode material layer while using a photoresist layer. Typically, the gate electrode material layer comprises a material other than silicon (i.e., typically germanium) where residues of such a material are transferred to the photoresist layer to provide a residue laden photoresist layer, and such residues are not susceptible to removal within an oxygen containing plasma that may otherwise be conventionally used for removing the photoresist layer. In order to avoid such a residue when removing the photoresist layer, the invention provides for a two-step nitrogen containing plasma etch method which: (1) first treats a surface layer of the residue laden photoresist layer to form a treated photoresist layer while using a first nitrogen containing plasma with an ion activation at a first temperature; and then (2) removes the treated photoresist layer from the gate electrode while using a second nitrogen containing plasma absent the ion activation and at a second temperature greater than the first temperature.

### EXAMPLE

Two substrates were prepared that included a base silicon substrate having a germanium layer of thickness about 1000 angstroms located thereupon, and further a germanium oxide layer of thickness about 200 angstroms located upon the germanium layer. Finally, each of the substrates included a photoresist mask located upon and covering about 30 area percent of the germanium oxide layer. The unmasked portions of the germanium oxide layers and germanium layers were then etched using a conventional plasma etch method that used a hydrogen bromide (i.e., HBr) and chlorine (i.e., Cl₂) etchant gas composition.

The photoresist mask was then stripped from one of the two substrates while using a downstream oxygen plasma stripping method that used: (1) a reactor chamber pressure of about 2 torr; (2) a source radio frequency power of about 5000 watts absent bias; (3) a substrate temperature of about 250 degrees centigrade; and (4) an oxygen flow rate of about 10000 standard cubic centimeters per minute.

The photoresist mask from the other of the two substrates was stripped using a two step nitrogen plasma stripping method in accordance with the foregoing embodiment that used particular parameters and limits in accordance with the foregoing embodiment.

Surfaces of the resulting patterned germanium and germanium oxide layer laminates were then inspected using a scanning electron microscopy method to ascertain the extent of any remaining photoresist layer residue. For the oxygen containing plasma stripping method a residue covered about 90 percent of the surface of the germanium oxide/germanium patterned layer laminate. However, for the two-step nitrogen plasma stripping method in accordance with the embodiment and the invention, the resulting germanium oxide/germanium patterned layer laminate was essentially free of any unetchable photoresist layer residue (i.e., much less than about 1 percent).

In accordance with the foregoing embodiment and example, the invention in particular thus provides a semiconductor structure that includes an essentially residue free germanium containing layer. The essentially residue free germanium containing layer may comprise germanium, a germanium alloy or a germanium oxide. The germanium containing layer may also comprise, but is not necessarily limited to a gate electrode, or a semiconductor substrate, that may in particular be used in a photonic microelectronic application.

The preferred embodiment and example is illustrative of the invention rather than limiting of the invention. Revisions and modifications may be made to methods, materials, structures and dimensions of a semiconductor structure in accordance with the preferred embodiment and example, while still providing a semiconductor structure that may be fabricated in accordance with a method of the invention, further in accordance with the accompanying claims.

What is claimed is:

1. A semiconductor structure including a patterned germanium layer having a photoresist layer etch residue of much less than about 1 area percent.

2. The semiconductor structure of claim 1 wherein the patterned germanium layer comprises a gate electrode within a field effect transistor.

3. The semiconductor structure of claim 1 wherein the patterned germanium layer comprises a semiconductor substrate.

4. A method for stripping a photoresist layer comprising:
treating a photoresist layer located over a substrate with a first nitrogen containing plasma that uses an ion activation to provide a treated photoresist layer located over the substrate; and
removing the treated photoresist layer from over the substrate with a second nitrogen containing plasma that does not use the ion activation.

5. The method of claim 4 wherein the ion activation is provided by using a substrate bias from about 20 to about 500 watts.

6. The method of claim 4 wherein the treating uses a first temperature and the removing uses a second temperature greater than the first temperature.

7. The method of claim 6 wherein the first temperature is no greater than about 130 degrees centigrade and the second temperature is at least about 200 degrees centigrade.

8. The method of claim 4 wherein each of the first nitrogen containing plasma and the second nitrogen containing plasma includes an inert carrier gas.

9. The method of claim 4 wherein the treating is monitored to an endpoint by using a carbon and nitrogen species detection method.

10. A method for forming a patterned structure comprising:
patterning a substrate to form a patterned substrate while using a photoresist layer located over the substrate as an etch mask layer;
treating the photoresist layer located over the patterned substrate with a first nitrogen containing plasma that uses an ion activation to provide a treated photoresist layer located over the patterned substrate; and
removing the treated photoresist layer from over the patterned substrate with a second nitrogen containing plasma that does not use the ion activation.

11. The method of claim 10 wherein the patterning the substrate includes forming a trench within the substrate.

12. The method of claim 10 wherein the patterning the substrate includes patterning a target layer which comprises the substrate.

13. The method of claim 12 wherein the target layer comprises a material selected from the group consisting of conductor materials, semiconductor materials and dielectric materials.

14. The method of claim 12 wherein the target layer comprises a gate electrode material layer.

15. The method of claim 14 wherein the gate electrode material layer comprises a gate electrode material selected from the group consisting of germanium containing gate electrode materials, metal gate electrode materials, nitride gate electrode materials and silicide gate electrode materials.

16. The method of claim 14 wherein the gate electrode material layer comprises a germanium material.

17. The method of claim 10 wherein the ion activation is provided by using a substrate bias from about 20 to about 500 watts.

18. The method of claim 10 wherein the treating uses a first temperature and the removing uses a second temperature greater than the first temperature.

19. The method of claim 18 wherein the first temperature is no greater than about 130 degrees centigrade and the second temperature is at least about 200 degrees centigrade.

20. The method of claim 10 wherein the treating is monitored to an endpoint by using a carbon and nitrogen species detection method.
